(19) United States
(12) Patent Application Publication
(10) Pub. No.: US 2026/0182468 A1
(43) Pub. Date: Jun. 25, 2026

(54) METHOD AND APPARATUS FOR REDUCING CONDUCTIVE METAL THERMAL EXPANSION WHILE MAINTAINING HIGH-FREQUENCY PERFORMANCE IN MULTIPLE-LEVEL SEMICONDUCTOR PACKAGING

(71) Applicant: Atlas Magnetics, Reno, NV (US)

(72) Inventor: John Othniel McDonald, Reno, NV (US)

(21) Appl. No.: 18/870,943

(22) PCT Filed: Jun. 2, 2023
(86) PCT No.: PCT/US2023/024378

§ 371 Date: Dec. 2, 2024

(51) Int. Cl. H10W 90/00

(52) U.S. Cl. CPC H10W 90/701; H10W 90/754

(57) ABSTRACT

The present invention involves the combination of relatively soft conductive material, such as copper, with a low thermal expansion metal alloy, such as Invar, by compositing the low thermal expansion alloy with porous insulation layering. By plating copper, and Invar composite together, the thermal expansion of copper is checked as the Invar prevents the copper from thermally expanding, but the Invar composite does not significantly reduce the electrical performance of the copper.

### FIELD OF INVENTION

The general field of the present invention is related to semiconductor-based integrated circuits and the passive components that are connected to them; more specifically, the field of the invention field is directed towards the methods of manufacturing high-performance passive components in multi-layer epoxy substrates that are a part of what is traditionally called the semiconductor package.

The integration of passives of the present invention inside the epoxy substrates promises to be inexpensive, physically smaller in the X & Y dimension, and marginally higher performance due to the passives' closer proximity to the silicon die.

### BACKGROUND OF THE INVENTION

The monolithic integration of passive components, such as inductors, oscillators, and various sensors in the multi-layer epoxy substrates, has at least four significant issues when creating passive components such as inductors, oscillators, and capacitors in the epoxy substrate. These issues are:
i) Limitations on the types of materials that can be used and the performance benefits those materials offer,
ii) The low melting point of the packaging epoxy limits the types of manufacturing processes that can be employed to create the passive components,
iii) The surface of the packaging epoxy is difficult to get good adherence to for many materials creating delamination issues, and
iv) The integration of dissimilar material with different thermal coefficients of expansions, even when bridging coefficients of thermal expansion (CTE), has a tendency to cause the large epoxy-based substrates to warp resulting in a substrate that cannot be used for post-processing into a final packaging integrated circuit “chip.”

Invar™, a well-known Nickel Iron Alloy of around 64% Iron and 36% Nickel with a near-zero thermal expansion coefficient, can be electroplated, is compatible with epoxy in terms of processing and process temperature, and with some care, can be made to adhere to the epoxy packaging resulting in low warpage. Invar, therefore, addresses or improves upon all four issues previously mentioned, with the only downside being the cost associated with the new process step.

Invar can also be combined in metal stack combinations with copper and various other metal alloys in precise ratios by various methods, including electroplating, to reduce the apparent thermal expansion of those other metals. Excessive thermal expansion/contraction may cause packaging cracks during operation, resulting in the field failure of the product. Thus metal-Invar-metal stacking or sandwich is often employed in high-power devices where temperatures are quite high and varying, which would otherwise result in significant and unacceptable thermal expansion and contraction.

Due to numerous potential benefits of using Invar, the material has been heavily patented over the prior decades for use in simple electronics prior to the semiconductor age, and then heavily again as circuits moved to the surface of silicon while being packaged in various methods from single injection molds to multi-layer substrates that are then over-molded to form the final “chip.”

However, Invar's use has been limited to thermal expansion control for power circuits for crack prevention or warpage control in the packaging while playing almost no role in the transmission of actual signals. The reason is quite simple, Invar has high permeability, and as such, signals passing through it will be severely limited by eddy currents resulting in a circuit that could only practically work in the sub 1 MHz range. The British patent GB 593632 A from the year 1945 taught a method of using a copper or silver-coated Invar™, a Nickel Iron Alloy wire to reduce the variation of a resonant circuit over temperature. At the time, sub 1 MHz was likely an excellent choice; however, today, the vast majority of power circuits and electronic signals operate far in excess of 1 MHz for many reasons, including size, accuracy, cost, and compatibility with interface circuits. Therefore, Invar without inventive input cannot be used in the same way as the circuits common today.

Therefore, it would be beneficial to have a cost-effective process by which Invar can be used in conjunction with modern multi-layer epoxy substrates and come in direct contact with electronic signals to offer the improvements associated with near-zero thermal expansion while not significantly harming the signal's signal to noise ratio “SNR” by blocking or significantly filtering the signal as the eddy currents of Invar or other similar nickel-iron alloys would.

The following is an implementation example of the problem the present invention attempts to solve: An LC oscillator's performance is particularly affected by thermal expansion. The temperature of the LC oscillator can change due to ambient temperature changes or through self-heating as power is dissipated in the LC tank circuit. LC Oscillators are often used in applications that demand higher frequency stability (+/−5% untrimmed 50000 ppm, or 500 ppm trimmed) vs. RC oscillators (commonly +/−20% (200,000 ppm) over process voltage and temperature), so much so they are often “locked” to another quartz oscillator which commonly has a frequency error of between (10 to 50 ppm over process voltage and temperature).

An LC oscillator's resonance frequency is related to the loop area of its inductor, and the loop area of the inductor will fluctuate as temperature change causes the material of the coil loops to expand or contract. Mathematically this relationship can be understood from the following equations:

$$f = \frac{1}{2 π \sqrt{LC}} \qquad ( 1 )$$

Here f is the resonance frequency, L is the inductance, and C is the capacitance. Inductance L, for solenoid type an air-core inductor is directly related to the loop size as can be seen from the following equation:

$$L = {μ}_{0} {KN}^{2} \frac{A}{l} \qquad ( 2 )$$

In (2) μ₀ is the magnetic permeability of free space, K is the Nagaoka constant where K≈1, N is the number of coil loops, A is the area of the loop, and l is the length of the coil.

Usually, an inductor coil is typically made from copper because copper is a relatively low-cost material with a very low impedance resulting in a desired high Q for the LC oscillator tank circuit example. However, copper has a ˜16 ppm/C coefficient of thermal expansion (CTE). Therefore, inductance in its simplest formulation, as given in (2), becomes a function of temperature T, because the loop area A and the length l are functions of temperature and can be represented by functions A(T) and l(T).

$$L ( T ) = {μ}_{0} {KN}^{2} \frac{A ( T )}{l ( T )} \qquad ( 3 )$$

On the other hand, due to the internal inductance, the wire used in the air-core inductor itself has some effect on the total inductance as well. Plane-wave skin depth δ, which characterizes the internal current distribution in a conductor, is given by the well-known formula,

$$δ = \sqrt{\frac{1}{π f {μ}_{0} {μ}_{r} σ}} \qquad ( 4 )$$

Where σ, μᵣ and f are conductivity, relative magnetic permeability, and frequency, respectively. Mainly μᵣ and σ also have significant temperature dependencies. Therefore, the relation (4) can be written as a function of temperature and frequency as

$$δ ( T , f ) = \sqrt{\frac{1}{π f {μ}_{0} {μ}_{r} ( T ) σ ( T )}} \qquad ( 5 )$$

For an air-core inductor made from copper windings the most temperature sensitive parameter in (5) is σ(T). In metals resistivity increases with temperature as,

$$ρ ( T ) = \frac{1}{σ ( T )} = {ρ}_{REF} [ 1 + α ( T - {T}_{REF} ) ] \qquad ( 6 )$$

Where ρ_{REF}, T_{REF} and a are reference resistivity, reference temperature, typically at 20° C. and temperature coefficient. Copper, iron, and Nickel α are 0.00393, 0.00567, and 0.00587, respectively.

The frequency stability of an LC tank circuit is directly related to the Q value of the tank circuit, which also is related to the resistivity of the inductor; therefore, this brings additional complexity to the problem!

These effects are enough to cause the resonant frequency of the LC circuit to shift significantly with temperature changes. But, if Invar is electroplated in mechanical connection to copper, then the composite material will roughly take on the combined performance of the materials with respect to the copper/invar ratio. However, the performance of the combined material over frequency is also heavily influenced by the surface characteristics of the material. Copper coated in thick Invar will result in a material that electrically appears to be Invar since electrons, due to eddy current limitations, flow on the outside of a conductor and, thus, at a high enough frequency, would flow close to exclusively through the Invar. The skin depth of the combined Invar and copper would thus push the electrons into Invar at high frequencies, making the copper essentially pointless. This was recognized in early 1945 patents with copper or silver being coated on the outside of the conductor for the electrical performance and Invar on the inside for thermal expansion performance, as this was true even for, in modern eyes, the low frequencies of that era.

Unfortunately, if Invar is electroplated on copper, given the high frequencies associated with today's circuits and Invar's high permeability, and the associated skin effect, the Invar must be very thin in order to avoid attenuating signals, so thin that the copper/invar ratio would be such that the invar would have almost no impact on the thermal expansion characteristics of the new composite material, it would essentially still be copper.

However, if there was a way to attenuate the eddy currents in the Invar in a manner that would allow a direct copper/Invar electroplated interface without significantly attenuating the signals flowing through the copper, then we could generate an MHz LC oscillator and various MHz electronic filters within multi-layer packaging that are passively (meaning without power) temperature compensated.

The following United States Patents and Patent Applications are incorporated by reference in full:
U.S. Pat. No. 5,098,533A: Electrolytic Method for the Etch Back of Encapsulated Copper-Invar-Copper Core Structures invented by Peter J. Duke and Krystyna W. Semkow
U.S. Pat. No. 5,128,008A: Method of Forming a Microelectronic Package Having a Copper Substrate invented by Pei C. Chen and Richard D. Weale
U.S. Pat. No. 6,589,413B2: Method of Making a Copper on INVAR® Composite invented by Chin-Ho Lee; Thomas J. Ameen; and John P. Callahan
U.S. Pat. No. 7,842,541B1: Ultra Thin Package and Fabrication Method Invented by Sukianto Rusli; Ronald Patrick Huemoeller; Bob Shih-Wei Kuo; and Lee John Smith
US 2020/0208289 A1: Electroplating Apparatus and Electroplating Method Using the Same invented by Kim Gotae, Yoo Byeongsun, Ahn Byungchul, Kim Woocha, Jeong Juyoung, Moon Sangcheol, Kim Wook, and Choi Changjun
US 2020/0208288 A1: Apparatus for Electro-Forming and Apparatus for Horizontal Electro-Forming invented by Yoo Byeongsun, Kim Woochan, and Kim Gotae
U.S. Pat. No. 6,518,509 B1: Copper Plated Invar With Acid Preclean invented by Galasco Raymond T, Mcclure Bonnie S, and Richards Craig W
US 2004/0011432 A1: Metal Alloy Electrodeposited Microstructures invented by Podlaha Elizabeth J, Murphy Michael C, and Namburi Lakshmikanth
U.S. Pat. No. 11,133,302 B2 Semiconductor Carrier with Vertical Power FET Module invented by L. Pierre de Rochemont

The following foreign patent applications are incorporated by reference in full
GB 593632 A: Improved Compensating Arrangements for Electrical Circuits Involving Inductance invented byJoseph Douglas Brailsford
KR 20020080065 A: Electrolytes for Fe—Ni Alloy Electroforming invented by Choi Jang Hyeon, Choi Jeong Hui, Hong Seung Hyeon, and Kim Deok Ryul

### BRIEF SUMMARY OF THE INVENTION

Embodiments of the present invention incorporate a conductive metal material, for example, copper and a nickel-iron alloy, for example, Invar, Kovar, or Super-Invar. The conductor and the nickel-iron alloy are both electroplated and patterned to form electrical components such as reduced temperature varying inductors, various sensors, and more thermally stable inductor cores directly on the surface of a multi-layered semiconductor packaging epoxy substrate in such a manner as to reduce cost, size, and improve the frequency response of the electrical component while still accessing the traditional value of low thermal expansion. However, to achieve the benefits of the present invention, the nickel-iron alloy is layered with a porous insulation layer that is designed to significantly reduce the eddy current formation within the Invar. The conductive material of the present invention may also be layered with the porous insulation layer.

The present invention also makes use of build-up films, for example, Ajinomoto Build-up Films “ABF,” which are epoxy and glass bead-based films and their equivalents which are in heavy use in the semiconductor packaging industry for multi-layer semiconductor substrates on which silicon die are placed as part of the final assembly of the IC package consisting of the Die(s), Substrate, and overmold.

The present invention makes use of industry-standard copper pillars to connect the silicon die to the electroplated substrate components with low resistance and almost no parasitic inductance and capacitance. The present invention allows for the creation of monolithically built components. These monolithically built components may be inductors, capacitors, and various sensors which commercially benefit from having a low CTE.

By monolithically building the equivalent Invar-enhanced component in the ABF-based multi-layer substrate vs. silicon surface, the manufacturing cost is substantially lowered, and often, the reliability is improved. By monolithically building the equivalent Invar-enhanced component in the ABF-based multi-layer substrate vs. externally on a printed circuit board, the electrical performance is improved, and often the reliability is improved. By monolithically building the equivalent Invar-enhanced component in the ABF-based multi-layer substrate vs. a System-in-package “SIP” component which is placed individually upon the multi-layers substrate, the manufacturing cost is lowered, and reliability is improved.

The combination of the present invention of high-accuracy ABF substrate film, copper pillars for interconnect, and cost-effective electroplating of copper and NiFe alloys, including Invar, allows for unique component shapes and component interfaces to the silicon die.

However, in all but the lowest frequency applications, nickel-iron alloys, for example, Invar, must be processed in such a manner for high-frequency signals to be applied directly or nearby. The Invar must be highly layered with an insulator that impedes the eddy current flow inside the Invar. The preferred embodiment of the metal and insulator layering will be by electroplating Invar at a thickness of between 0.5 um and 2 um. The entire Invar composite layered stack will vary depending on the application. However, practical values are between 10 to 40 um. implying between 5 to 80 layers of Invar. Typically this type of extensive layering is expensive.

The present invention may make use of porous insulation layering, also known as CCVD-type porous insulation, as a layering material to magnetically and electrically decouple the copper from the NiFe alloys by embedding in either the conductor, NiFe alloy, or both. SiO₂ porous insulation is a fast, low-cost, environmentally safe material that can be deposited at temperatures compatible with the epoxy-based substrate and the patterning dry film.

A porous insulation layer deposits in such a manner that voids remain in the insulative coating-thus giving it the name “porous insulation layer.” In the present invention, the coverage is ˜95% but can range from 80% to 97%. These “voids” are important in lowering the cost of the layering process as they are insulative enough to block most of the eddy currents but still allow a direct electrical connection to the next layer. Because the prior layer forms the new electroplating electrode for the subsequent layer, the patterning dry film does not need to be removed and replaced with each layer, there is no need for an additional electroless seed layer, and the process can be reduced from ˜14 steps to 4 steps.

The porous insulative layer voids are also mechanically important as they tie the various layers directly together in a single material. Due to the tight layering, the highly layered material can be modeled as a new material composite material with its own coefficient of thermal expansion which is very close to standard electroplated nickel-alloy material which forms the metal layers of the composite; however, electrically, the new composite material has 5 to 20× higher resistivity and thus has much improved high-frequency characteristics allowing practical, direct connection of the nickel-iron alloy composite to copper to the GHz range.

The porous deposits are preferred to be between 20 to 100 nm thick as measured immediately after deposition. Too thick allows for too many voids and increased eddy currents: too thick slows the electroplating processes and, in some cases, can stop the layering process altogether. The layering process does not need to be consistent, and there is some benefit to having thinner layers closer to the copper interface and thicker Invar composite layers further away for cost reasons and to further decouple the electrical performance of the copper from the Invar.

In this invention, the consistency, roughness, and planarity of the Invar composite layers influence the performance of the new composite material. ABF is produced with an average roughness of ˜50 to 100 nm; however, in many cases, the surface of the ABF is intentionally roughened to enhance the adherence of the next ABF layer in the multi-layered substrate manufacturing. This intentional roughing can result in a height difference from film peak to valley up to 5 pm. If nothing is done to reduce this roughness, then when plating the first layer of Invar, for example, the 1 pm layer is hardly flat and consistent but often appears jumbled. Further, due to the rough surface and the roughly perpendicular deposition of the porous insulation layer, the first few layers are highly disorganized. Despite the highly disorganized nature of these first layers, if layering continues, the layers generally become more consistent and flat due to the leveling agents in the electroplating solution. While no additional effort to reduce roughness is required to achieve an economically viable CTE-reducing material, a smooth, nicely ordered layered material is desired for many reasons, including: manufacturing consistency, correlation to models, better magnetic performance for the NiFe alloys on which this is desired, consistent coverage.

In this invention, there are many methods to improve the layering consistency, even when using pre-roughened ABF. The preferred method is to electroplate the first few microns until every peak is covered and then grind the entire ABF epoxy-based substrate or panel containing multiple substrates with an industry-accepted method of grinding or chemically polishing the surface to nanometer accuracy and then start the normal layering process.

In this invention, there are methods to improve ABF adherence and thus remove the pre-roughening process step. These methods include: creating the passive components first before placing the ABF, this requires the ABF substrate to be flipped during the manufacturing process; using the porous insulation layer to precoat the ABF substrate to energize the surface to improve adherence before the next layer of ABF is deposited.

Depending on the thermal behavior of the attached circuitry of the silicon die, the desired thermal expansion adjustment caused by copper/porous insulation enhanced Invar ratio on the in-package component need not be as low as possible but rather equal and opposite to the silicon circuit such that the system when connected together achieves as low of thermal variation as possible.

The present invention may also make use of one or more NiFe alloys simultaneously. NiFe alloys such as 10/90, 36/64, 45/55, and 80/20 have different thermal expansion coefficients, resistivity, and permeability. Each alloy is used in the electronic industry as suited for a particular application. In the present invention, we may make use of multiple NiFe alloys electroplated from the same electroplating bath with only temperature and electroplating current frequencies and levels being changed to cost-effectively take advantage of the particular NiFe alloy characteristics. This ability to electroplate more than one NiFe alloy cost-effectively can be extended to tri-metal alloys as well, such as CoNiFe, which further expands the component engineers' tool suite. All NiFe alloys tested to date can make use of the porous insulation layer enhancement to allow the magnetic and mechanical properties of these materials to be used at much higher frequencies than the bulk NiFe alloys alone.

Further, the present invention can apply essentially the same porous insulation layering process to the copper being electroplated with the NiFe alloy for improved frequency performance of the copper, and both the copper and NiFe alloys can be highly layered with porous insulation.

Thus, embodiments of the present invention may include a composite material comprising: electroplated nickel-iron alloy with at least one porous insulative layer at any interval. This composite material may be operationally connected to at least one epoxy base. The epoxy base may be but is not limited to being a fiberglass-impregnated epoxy board or film, a glass bead-impregnated epoxy board or film, or a pure epoxy board or film. The epoxy base itself may be operably connected to a multi-layer substrate carrier board.

The incorporation of epoxy and multi-layer substrate boards allows the composite material to seamlessly fit and blend with multi-layer packaging allowing the composite material to serve in multi-layer packaging because multi-layer epoxy packaging is also made with epoxy materials.

The composite material may be operably bonded to the composite material on at least one surface of the composite material. In at least one exemplary embodiment, the conductive material is copper. The conductive material as copper or another conductive material, which is plateable, may be layered with porous insulation and mechanically bonded to the composite material on at least one side of the Invar composite.

Together the composite material and copper material may be configured as, by forming such a component, an operable electrical component. Such a component may be an active component or a passive component. The passive component may be an inductor. The inductor may be incorporated into an LC oscillator, for example, but the passive and active components which may be formed and the systems which they are incorporated into are not limited to inductors and LC oscillators but mainly by the choice of material. One of the ordinary skills in the art will know many components which are based on conductive materials, including copper.

One unique aspect of the present invention beyond the primary function of allowing Invar and other nickel-iron alloys to be practically used with electrical systems without significantly affecting the electrical performance of those components is that because Invar or other alloys may be strong, weaker copper structures may be formed which rely on the nickel-iron alloy composite material for structural strength. Thus the conductive material of the present invention's passive component may have a mechanically weak structure. For example, Invar lends its strength to the conductive material. Thus it is important to note that in at least one embodiment, the nickel-iron alloy is Invar which is a high-strength nickel-iron alloy.

At least one exemplary embodiment has at least one boundary layer operably located between the conductive material and the composite material layer itself. This boundary layer may be a porous boundary layer as this allows the two materials to be bonded to each other through the boundary layer.

Other alloys of materials may be used to form the composite material; for example, cobalt may be added to the nickel-iron alloy to form nickel-iron-cobalt alloys. This allows nickel-iron-cobalt alloys such as Super Invar or Kovar to be used.

Because these alloys, both nickel-iron alloys and nickel-iron-alloys, may be used to control thermal expansion in multi-layer packaging through the formation of composite materials incorporating these alloys, the present invention allows for a method of controlling the thermal expansion of conductive materials in multi-layer packaging comprising; Operably bonding an Invar composite material, (the nickel-alloy iron of the composite material may be Invar, and when it is Invar, the composite material may be referred to as an Invar composite material) to a conductive material; and encapsulating the Invar composite material with epoxy plastic.

As Invar need not be electrically utilized, being used primarily instead for its structural properties and resistance to thermal expansion, the conductive material itself may form the passive. In such cases, both the conductive material and the Invar may be encapsulated, and ABF plastic may be used for the encapsulation. This may be achieved by placing the first layer of ABF onto the Invar composite material bonded conductive material, flipping the ABF, forming a porous boundary layer on the ABF, and depositing additional ABF. The result may be an Invar composite material strengthened passive component embedded in multi-layer packaging.

### BRIEF DESCRIPTION OF THE FIGURES

FIG. 1 A flowchart showing the method of creating an Invar composite material.

FIG. 2 shows a cross-section of Invar composite material bonded to the conductive material on its upper and lower surfaces.

FIG. 3 shows a cross-section of a conductive material operably bonded to Invar composite material along its upper and lower surfaces.

FIG. 4 shows a cross-section of a conductive material operably bonded to Invar composite material along two adjacent surfaces.

FIG. 5 shows a cross-section of a conductive material operably bonded to Invar composite material along three adjacent surfaces.

FIG. 6 shows a cross-section of a conductive material operably bonded to Invar composite material along all its surfaces.

FIG. 7 shows a cross-section of a conductive material operably bonded to an Invar composite material core. There is a porous boundary layer between the core and the conductive material.

FIG. 9 shows a cross-section of a conductive material operably bonded to an Invar composite material core and encapsulated in epoxy plastic. There is a porous boundary layer within the epoxy plastic.

FIG. 9 shows a cross-section of Invar composite material operably bonded to an epoxy board.

FIG. 10 shows an inductor coil sitting on the Invar composite material base.

FIG. 11 shows a cross-section of Invar composite material and conductive material where the conductive material is a weakened spring shape.

FIG. 12 shows a cross-section of repeating Invar composite material pillars with conductive pillars.

FIG. 13 shows a close-up of a cross-section of porous insulation material where a layer of alternate metal has been electroplated over the insulation layer.

FIG. 14 shows a flowchart of a method of incorporating a passive operably bonded with the invar composite material into multi-layer packaging.

### DESCRIPTION OF THE INVENTION

In at least one embodiment of the present invention, an epoxy substrate, Ajinomoto build-up film or equivalent (for example, an epoxy film impregnated with glass beads) is used as a base for an electroplated nickel-alloy layer, and a copper layer is operationally electroplated onto the nickel-iron layer. Depending on the application, one or more surfaces of the nickel-iron may be mechanically connected to the nickel-iron base.

Nickel-iron alloy is not used to bridge the CTE of conductive metal and the substrate, but it works to lock the expansion of the conductive metal. Invar, for example, is a strong nickel-iron alloy having a CTE of 0.62-0.65 ppm/° C. when pure, which is even lower than, although close to, the 2.6.10-6° C.-1 CTE of silicon typically used as a semiconductor substrate. However, Invar has a higher strength than either silicon or copper, to which it would be bonded. So, when, for example, under most temperature conditions, as the copper changes temperature and seeks to expand, the Invar will not be pulled by the copper and thus will not expand. Given that the Invar is stronger than the expansion force of the copper, the Invar will prevent the copper from undergoing linear expansion along the surface of the bonded Invar and copper. If the Invar or other nickel-iron alloy was weaker than copper in this regard, the expansion of copper would stretch it and may even pull it apart.

However, in all but the lowest frequency applications, pure nickel-iron alloy will greatly attenuate any signal in the adjoining copper material due to parasitic eddy currents when the signals are raised in frequency according to well-known skin effect calculations. Therefore, the nickel-iron alloy must be layered with an insulator. The insulator's function is to raise the resistivity of the nickel-iron alloy and thus reduce the eddy currents allowing the nickel-iron alloy to do less harm to the high-frequency response of the adjoining copper material while still providing the benefits of a low thermal expansion coefficient. Layering is usually an expensive process made up of a pre-seed condition process, seed layer, cleaning, dry film application, electrodeposition, cleaning, dry film removal, etching, cleaning, ABF application, roughening, etc.

In at least one exemplary embodiment, the conductive material is a metal, for example, copper, and the nickel-iron alloy is Invar. This invention incorporates porous insulation layers which allow the Invar and various low CTE alloys of Co, Ni, and Fe to be electroplated right through the insulation layer. This is accomplished by the insulation layer being deposited by Combustion Chemical Vapor Deposition (CCVD), open-air atmospheric pressure plasma enhanced chemical vapor deposition “AP-PECVD”, or a void printing process. In the preferred embodiment, the porous insulation layer comprises SiO₂, but in other exemplary embodiments may be, but is not limited to Nitride, TiO, SiO₂ or SiO₂+TiO, or a combination of these materials. These aforementioned forms of deposition form porous insulation layers as the layers are filled with voids, pinholes, and small cavities such that, in one exemplary embodiment, only ˜95% of the surface to be coated by the deposition process receives the insulator. Due to these “voids,” the prior layer of Invar can be used as an electroplating electrode for the next layer of Invar without having to go through prepping a seed layer, adding a new seed layer, the cleaning steps in between, a new dry film layer and its removal. In total, only 4 significant process steps are left when this new method of placing an imperfect CCVD insulation layer greatly speeds up and simplifies the process. Numerous insulating materials are able to be CCVD deposited, and these can be used in place of SiO₂. However, SiO2 is preferred due to its effectiveness, cost, and excellent safety profile.

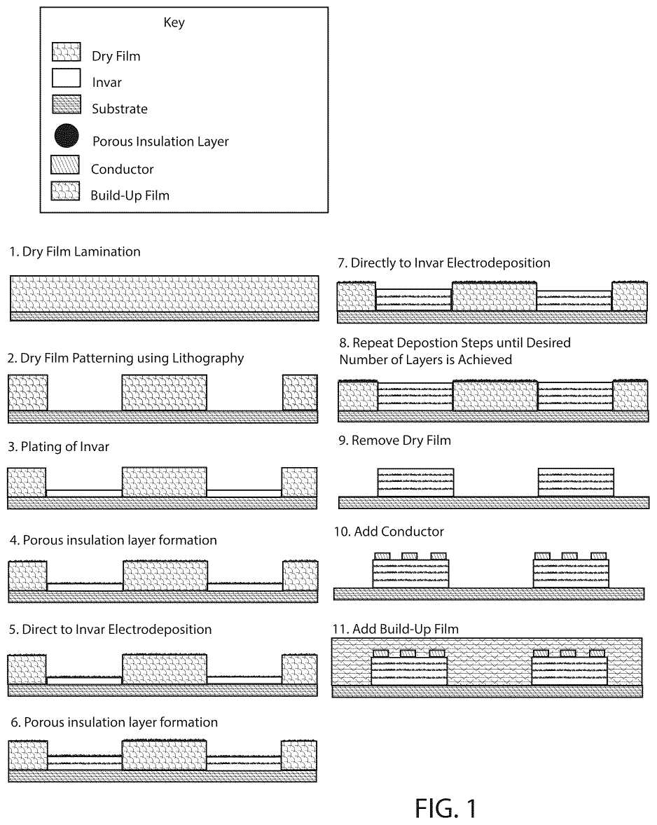

FIG. 1 shows a flow chart of an exemplary embodiment where a composite Invar material is built by porous insulation deposition. In FIG. 1, an Invar component layer is being built up so that the Invar has porous insulation layers running through it. In Step 1, a dry film lamination is placed, Step 1 may occur on the substrate or on copper or other conductors; in Step 2, the pattern is produced; in Step 3, the Invar is electrodeposited; in Step 4, the porous insulation layer is produced; in Step 5, Invar is again deposited; in Step 6, a porous insulation layer is formed; in Step 7, Invar is again deposited; as Step 8, shows, the layering steps may be repeated as desired; and Step 9 shows the removal of the dry film. A conductive material, for example, copper, may then be deposited onto the Invar composite material, as shown in Step 10, and may be encapsulated in epoxy plastic, for example, build-up film, as shown in Step 11. In at least one exemplary embodiment, Step 11 is skipped, and in at least one embodiment, at least one non-conductive material is placed instead of or in addition to a conductive material before Step 11 occurs.

This process can be repeated on an epoxy base, for example, fiberglass impregnated epoxy board or film, a glass bead-impregnated epoxy board or film, or a pure epoxy board or film. Further, after completion of the Invar and removal of the dry film, build-up film may be placed, thus integrating the Invar or conductor and Invar-based component into packaging.

The new composite material has its own unique resistivity that is dependent on the layering thicknesses and quantity of layers. However, the insulation layers are thin and mechanically imperfect such that the composite material still retains most of its desired native CTE characteristics. As noted above, in at least one exemplary embodiment, other alloys or pure metals, including Co, Ni, and Fe can be used in place of Invar, two of which are trademarked as Super Invar, and Kovar. (Super Invar™ is another low thermal expansion coefficient material made of 32% Nickel, 5% Cobalt, and the remainder being Iron. Kovar™ is a low thermal expansion coefficient material made of 29% Nickel, 17% Cobalt, and the remainder being Iron.)

The new Invar composite material can be placed in mechanical connection in a myriad of ways to copper or silver, or any other highly conductive metal to what is effectively the equivalent of reducing the overall system CTE. By incorporating nickel-iron alloys, which work to reduce the effective CTE of a system to that of the alloy, circuit systems can be formed which have a high degree of stability in properties over a wide range of temperatures. The potential stability, with Invar, for example, is greater than what is achieved by bridging the CTE by layering material from the highest CTE material to the lowest CTE material. The result of a bridge is more thermal expansion and a thicker component than the process of bringing in a base layer, such as Invar, that has a lower CTE and holding the entire system to, or near to, that standard. Bridging CTE also separates the highest and lowest CTE materials of the system, but an Invar system puts the highest and lowest CTE materials directly together.

The CTE of the system can be controlled and need not be set to the lowest CTE but can be set to other values by controlling the thickness and amount of Invar. For example, the CTE of the copper and Invar can be set to equal and opposite to the silicon circuit, such that the system, when connected together, achieves as low thermal variation as possible. Many iterations and combinations of nickel alloy and conductive material may be provided, the variety is not limited to that shown herein.

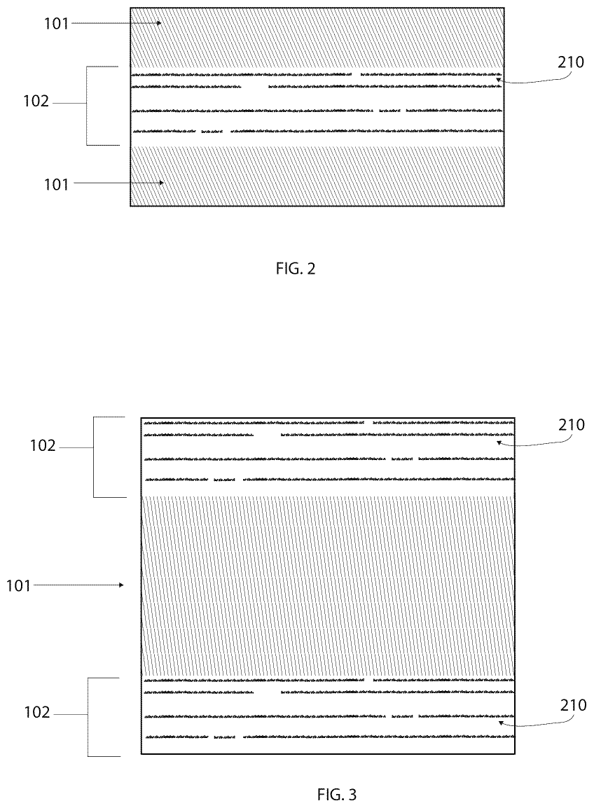

FIG. 2 shows a composite Invar composite layer 102 with porous insulation layers 210 sandwiched between two copper layers 101. This provides strong directional expansion control as temperatures change. The nickel-iron alloy is strong enough to provide expansion control to more than one layer of the conductor.

During the manufacturing process, as the Invar composite base layer is built on, or even as the thickness of the copper layer is increased, the single Invar base layer may not be able to prevent the linear expansion of the higher portions of the built element. Therefore, in at least one exemplary embodiment, at least one additional layer of nickel-iron alloy is operationally bonded to the conductive material; the second Invar composite layer is operationally bonded to the copper layer. Here the conductive material may be copper, for example, and the nickel-iron alloy Invar, for example.

In this case, the second Invar composite layer may reside along the surface of the copper layer opposite the first Invar composite layer, as shown in FIG. 3. This allows Invar composite layer 102 to work together to prevent the expansion of copper layer 101 along the same plane. In at least one exemplary embodiment, the second Invar composite layer may be placed upon whatever is built on the first copper layer; thus, there is an intermediary layer between the conductor and the Invar. In further embodiments, the second Invar composite layer may be built upon as well, and another Invar composite layer plated, and this process may be repeated, and this process may be used to build the example shown in FIG. 3. The second Invar composite layer may be placed on alternate surfaces of the copper layer besides the surface opposite the first layer—and as such, the placement is not limited to the opposite surface of the copper layer from the surface of the copper and Invar bond. This can be beneficial as it may serve to completely eliminate the direction of the copper layer's expansion.

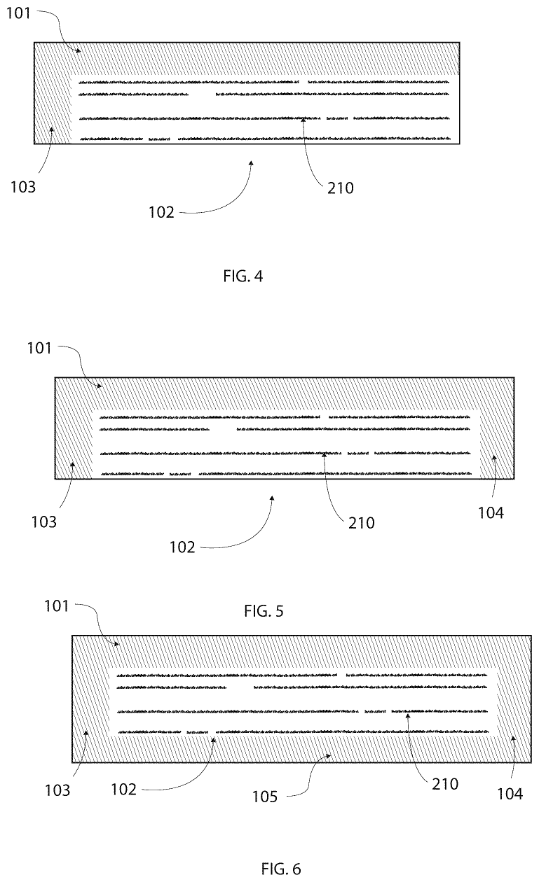

It may also be beneficial to plate copper on multiple sides of the Invar as well, and an example is shown in FIG. 4. Here, two sides of the Invar composite layer 102 are plated with copper. Thus there is a copper layer 101 and copper layer 103 the Invar composite layer 102 controls the copper layers from expanding against the plane of the surface the copper is bonded to copper with. The surface where copper and Invar are bonded together may be chosen according to the desired direction for Invar to control the expansion of copper in.

As shown in FIG. 5, A third copper layer 104 may be plated onto another empty surface of the Invar composite layer 102.

The Invar composite layer need not be bonded to the substrate or connected to it directly by other means; as such, the base Invar composite layer may have at least one copper layer operationally bonded to each of its surfaces so that all surfaces of the Invar base layer are operationally bonded to copper. This forms an Invar core within the copper layer that is effective at preventing the thermal expansion of the copper-plated around it. (The inverse holds true in at least one embodiment so that there is a shape of Invar with a copper core.) If the Invar composite base layer is not to be plated onto a substrate or to some other portion of a circuit, the copper may be plated on all but one side of the copper, as shown in FIG. 6, where there is now an underlayer 105 of copper, to create several embodiments where the surface of the Invar composite layer 102 is not bonded to any substrate.

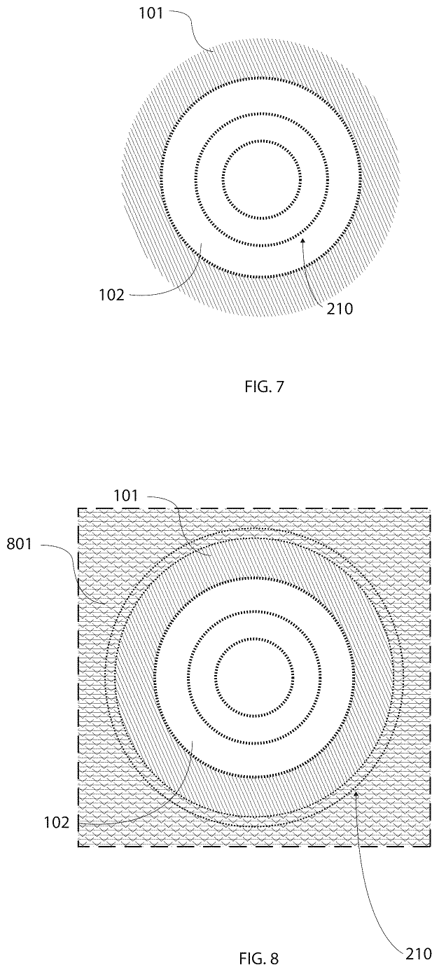

The number of surfaces of the copper layer that can be plated with Invar is limited only by the number of surfaces of Invar composite. When forming a core of Invar, the base Invar composite layer may be in the shape of a cylinder upon which the copper is plated, as shown in FIG. 7. Here, copper layer 101 surrounds the entirety of Invar composite 210 such that Invar composite 210 forms an internal core for the copper 101. This allows Invar to serve as an effective limiter of CTE in-circuit elements that require or are improved by the use of cylindrical conductors. These cylindrical conductors may be wires; therefore, by plating a cylindrical Invar composite layer with copper, a wire can be formed that is highly resistant to CTE. In such cases, copper would cover all of the Invar, as the Invar would serve as an internal strengthening pillar as Invar should not block but allow the copper to be able to connect to the rest of a circuit electrically. Therefore, the copper may have one surface connected to some other portion of the circuit.

FIG. 7 also shows that Invar composite 102 has a porous boundary 230, which is on the boundary of the copper and Invar composite. This boundary layer allows the copper and Invar of the Invar composite to be directly bonded to each other but helps prevent electrical connection between the Invar and copper. In each embodiment, there is not a porous boundary layer 230 between the copper and the Invar; there is an embodiment with this porous boundary layer 230 of copper, and Invar can be applied where Invar and copper are connected.

These components are compatible with epoxy plastics, and therefore they are suitable for integration into multi-layer packaging. In FIG. 8, copper 101 plated around an Invar composite core 102 with porous insulation layers 210 is encapsulated by ABF build-up film 801. This packaging operably serves as packaging for the multi-layer component. One porous insulation layer 210 is in the ABF layer 801, and this initial layer has been placed to increase ABF adhesion between an initial ABF layering and additional ABF. This process is further discussed in FIG. 14.

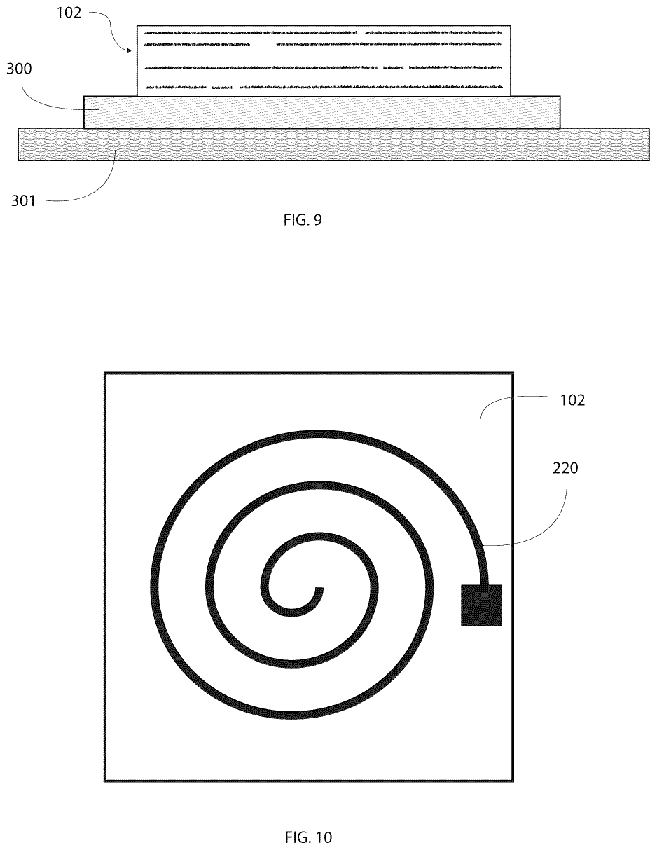

There are several additional considerations beyond which surface of the Invar to cover in the copper selection that result in several embodiments of the present invention. The first is the ability of the Invar composite to serve as a base layer, as this increases the ease of manufacturing and sets the Invar on the substrate. To achieve this, the Invar may be first plated onto the semiconductor substrate or epoxy, as this “sets” the Invar composite onto the substrate, as shown in FIG. 9. Here, Invar composite 102 has been plated onto the epoxy base 300. If an epoxy base is used, for example, a fiberglass-impregnated epoxy board or film, a glass bead-impregnated epoxy board or film, or a pure epoxy board or film, the epoxy base may be operably connected to a multi-layer substrate carrier board. Copper or other conductive materials may be plated onto the Invar and over-molded. The epoxy base may be further operably connected to a substrate carrier, for example, a multi-layer substrate carrier board 301.

As noted above, since the Invar and copper can be plated and patterned according to electroplating means, the copper-plated Invar may be shaped and used as a conductive component for a variety of electrical components so that in semiconductor systems, the copper layering can serve as a conductive component for an integrated active component, as the conductive component for an integrated passive component, or as the other elements of the system that may be created out of copper or conductive material. For example, the copper and Invar composite layering can be shaped and dimensioned to that is configured as an inductor, including but not limited to spiral, solenoid, toroid inductors. These inductors can, in turn, be incorporated within multilayer packaging to help form transformers and coupled inductors. However, the invar and copper combination can also be shaped and dimensioned such that capacitors and resistors, for example, are formed. In fact, by exemplary embodiments, all electrical components within microelectronics which utilize copper may be formed. Thus the Invar and Copper conductors can be used in sensors, for example, inductive touch and position sensors, as well as in or to produce higher level system integrated circuits, including Power Management IC “PMICs,” Phase Lock Loops “PLL,” or LC Oscillators. This is achieved by plating composite Invar so that it holds the copper or other metal conductor of such circuits in place under thermal stresses.

To further the ease of using Invar plated copper to be used across a wide range of systems, the copper layer need not match the underlying Invar composite layer. Therefore, the Invar composite layer may serve as a solid base layer, and the copper layer may form some design upon the surface of the Invar, which is not matched by the Invar composite layer. This allows the Invar composite 102 to serve, for example, as the base layer for an inductor 220 where the copper of the inductor 220 coils sits on a large base of Invar composite 102, as shown in FIG. 10. This inductor could be covered in epoxy plastic and thus sit in-package.

In certain inductor types, such as planar inductors, this works to prevent the coils of the inductor from expanding due to thermal changes in a manner that alters the coil area. As dictated by the demands of the component, the Invar may be plated all around the component, save for a desired connection point, so that the component will not expand. An example embodiment can be found in three-dimensional coiled inductors (or any wire), as the copper coils may need to be surrounded by Invar, leaving only a connection point at each end of the inductor to prevent thermal expansion.

An inductor having coils controlled for thermal expansion is excellent for a variety of uses, including as an inductor in an LC oscillator component. Therefore, a particular embodiment of the present invention is an inductor in an LC oscillator circuit. By controlling the thermal expansion of the inductor coils, the coils will present a stable area over a wide range of temperatures, and this, in turn, stabilizes the resonant frequency of the LC oscillator. A stable frequency allows for LC oscillators with narrower resonant frequencies to be created and used in commercial or industrial systems that will be exposed to a wide range of temperatures and environments around the world. This is because, without stability, the resonant frequency must be wide enough to send or receive the proper signal across the range of temperatures that will change the frequency from the LC oscillators.

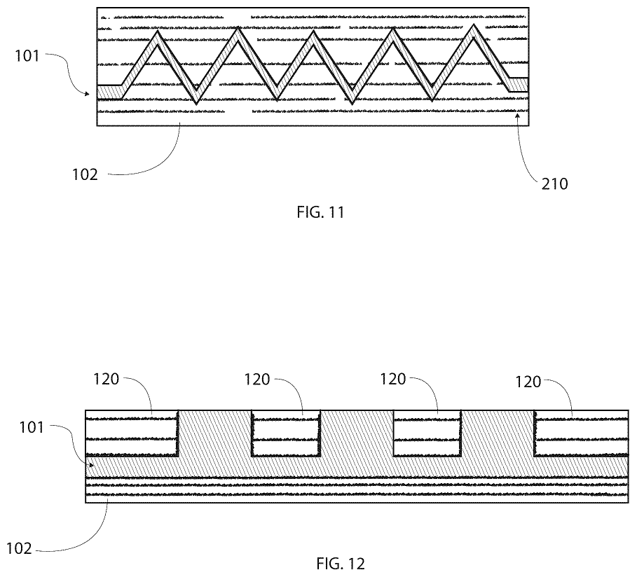

While the copper-plated Invar composite is well suited to adoption into electrical components, it also allows for the design of circuit elements to be changed to further reduce manufacturing costs for high-end components where near absolute precision among desired properties is needed across a wide variety of thermal environments. Invar composite is a strong material and is able to hold copper in certain shapes. Thus, the copper 101 itself can be formed in a weakened structure such as a series of repeating acute angles, as shown in FIG. 11 where copper 101 has been shaped into a series of repeating angles and set in Invar composite 102. Forming the copper in this shape without the invar composite layer would cause the acute points of the copper to break or at least change angles due to expansion and contraction across a variety of temperatures. Use of Invar composite material enables these copper formations to be used in packaging under real world conditions without breaking.

In at least one exemplary embodiment, the copper itself can be shaped to limit the property-altering thermal expansion of a component to predetermined planes, and Invar can then be used to eliminate the thermal expansion among these planes. One such shape is that of a two-dimensional spring where the copper is a line of repeating acute angles. Although it would be likely to break if expanded too far, under only low temperatures variation, these angles would act as a spring so that the copper line would appear to extend or contract, and thus the properties of the component the copper is used for would change. Plating this copper line on an Invar base will prevent the copper spring from moving. Thus Invar allows weaker copper structures to be used as weak copper structures would break or change shape due to thermal expansion. In the same vein, Invar thus allows less copper to be used.

In at least one exemplary embodiment of the present invention, Invar can be used to strengthen copper pillars. This is achieved by plating an Invar composite base layer 102, placing a copper layer 101 onto the Invar composite base layer 102, plating copper pillars onto the copper layer, and then plating the spaces between the copper pillars with Invar composite to form Invar pillars 120, for example, as shown by FIG. 12.

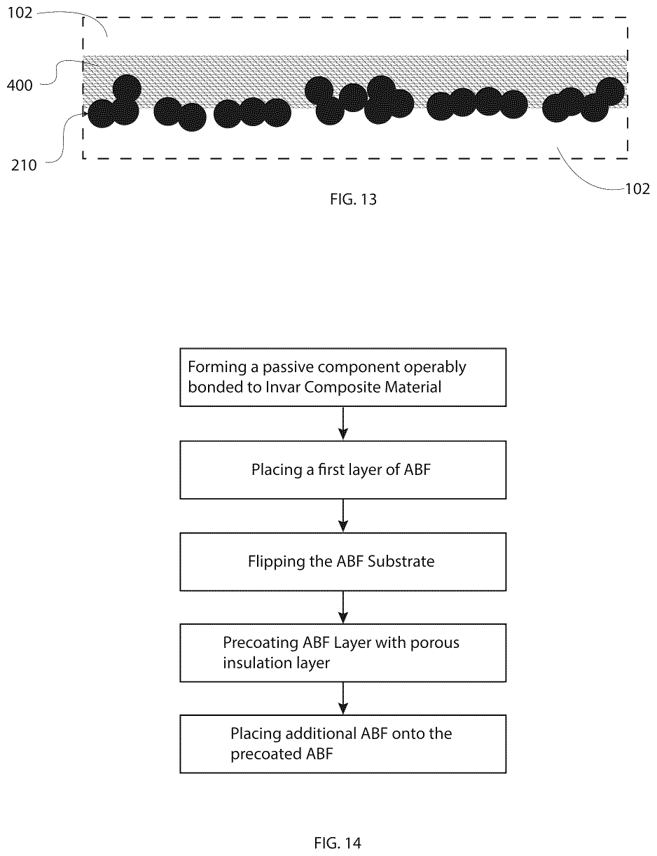

In at least one exemplary embodiment, to further increase the resistivity of the nickel-alloy and copper component, a thin layer of a high resistivity metal 400 as compared to nickel-iron, such as NiP, may be electroplated immediately after the porous insulation deposition at a thickness roughly equivalent to the porous insulation thickness 210 for the purpose of raising the total resistivity of the insulation layer to further reduce eddy currents. An example result is shown in FIG. 13.

This present invention includes low thermal expansion nickel alloys such as, but not limited to, the alloys trademarked Invar, Super-Invar, and Kovar. The applications of the present invention are not limited to those discussed herein; for instance, the Invar can be used under an RF antenna to stop the thermal expansion of the antenna within a multi-layer substrate semiconductor packaging. The words metals and alloys are used interchangeably. The preferred embodiment of this invention is integrated into multi-level semiconductor packaging processes and substrates, including 3D packaging.
a. In at least one exemplary embodiment of the present invention, the nickel-alloy composite material is operably bonded with a conductive material to form a passive component operably bonded with Invar composite material into multi-layer packaging. In at least one embodiment: a passive component operably bonded with Invar composite material is formed on epoxy plastic, a first layer of ABF is placed, the substrate is flipped, the substrate is then coated with a porous insulation layer, and additional ABF is then placed as shown in FIG. 14

This allows for improved ABF adherence as the porous insulation layer used to precoat the ABF substrate will energize the surface to improve adherence before the next layer of ABF is deposited.

Therefore, this invention allows for the incorporation of high-strength metal alloys, for example, nickel-iron and nickel-iron-cobalt alloys, and particularly Invar, to be incorporated into the component design in multi-layer packages by specifically modifying the alloy so that it is electrically insulative and does not significantly affect the performance of the conductor, for example, copper. By allowing the high-strength metal alloys to be used in this manner, in-package component design can be modified as weaker conductive structures are now possible as the high strength of the alloys provides the necessary structural support.

The drawings and figures show multiple embodiments and are intended to be descriptive of particular embodiments but not limited with regard to the scope or number, or style of the embodiments of the invention. The invention may incorporate a myriad of styles and particular embodiments. All figures are prototypes and rough drawings: the final products may be more refined by one skill in the art. Nothing should be construed as critical or essential unless explicitly described as such. Also, the articles “a” and “an” may be understood as “one or more.” Where only one item is intended, the term “one” or other similar language is used. Also, the terms “has,” “have,” “having,” or the like are intended to be open-ended terms. Both the methods and the varied apparatus of the present invention are intended to be claimed. Invar is also or has been known as UNS K93600, Invar 36, NILO 36, Supra 36, and Pernifer 36.

1. A composite material comprising:
electroplated nickel-iron alloy with at least one porous insulative layer at any interval.

2. The composite material of claim 1, further comprising the composite material operationally connected to at least one epoxy base.

3. The composite material of claim 2, wherein the epoxy base is a fiberglass-impregnated epoxy board or film, a glass bead-impregnated epoxy board or film, or a pure epoxy board or film.

4. The composite material of claim 3, further comprising the epoxy base operably connected to a multi-layer substrate carrier board.

5. The composite material of claim 2, further comprising a conductive material operably bonded to the composite material on at least one surface of the composite material.

6. The composite material of claim 5, wherein the conductive material is copper.

7. The composite material of claim 5, wherein the conductive material is layered with porous insulation and mechanically bonded to the composite material on at least one side of the Invar composite.

8. The composite material of claim 6, further comprising the composite material and the conductive material configured as an electrical component.

9. The composite material of claim 8, wherein the electrical component is a passive component.

10. The composite material of claim 9, wherein the passive component is an inductor.

11. The composite material of claim 10, wherein the inductor is an inductor in an LC oscillator.

12. The composite material of claim 10, wherein the conductive material of the passive component has a mechanically weak structure.

13. The composite material of claim 1, wherein the nickel-iron alloy is Invar.

14. The composite material of claim 5, further comprising at least one boundary layer operably placed between the conductive layer and the composite material layer.

15. The composite material of claim 14, wherein the boundary layer is a porous boundary layer.

16. The composite material of claim 1, further comprising the nickel-iron alloy incorporating cobalt to form an alloy of nickel-iron-cobalt.

17. The composite material of claim 16, wherein the nickel-iron-cobalt alloy is Super Invar or Kovar.

18. A method of controlling the thermal expansion of conductive materials in multi-layer packaging comprising;
Operably bonding an Invar composite material to a conductive material,
and encapsulating the Invar composite material with an epoxy plastic.

19. The method of claim 18, wherein the conductive material forms a passive component, an ABF plastic is used for the encapsulation, and the conductive material and the Invar composite material is encapsulated by placing a first layer of ABF onto the Invar composite material bonded conductive materiel, flipping the ABF, forming a porous boundary layer on the ABF, and depositing additional ABF.

20. The method of claim 18, wherein the epoxy plastic forms a multi-layer packaging substrate.
